(19) United States
(12) Patent Application Publication
(10) Pub. No.: US 2025/0063870 A1
(43) Pub. Date: Feb. 20, 2025

(54) LIGHT-EMITTING DEVICE AND METHOD FOR MANUFACTURING SAME

(71) Applicant: NICHIA CORPORATION, Anan-shi (JP)

(72) Inventor: Takahito MIKI, Tokushima-shi (JP)

(73) Assignee: NICHIA CORPORATION, Anan-shi (JP)

(21) Appl. No.: 18/939,488

(22) Filed: Nov. 6, 2024

Related U.S. Application Data
(63) Continuation of application No. PCT/JP2023/019402, filed on May 24, 2023.

(30) Foreign Application Priority Data
May 30, 2022 (JP) 2022-087869
May 19, 2023 (JP) 2023-083178

(51) Int. Cl. H01L 33/60; H01L 23/00; H01L 25/16; H01L 33/50; H01L 33/56; H01L 33/58; H01L 33/62

(52) U.S. Cl. CPC H01L 33/60; H01L 24/16; H01L 25/167; H01L 33/50; H01L 33/56; H01L 33/58; H01L 33/62; H01L 2224/16157; H01L 2924/12035; H01L 2924/12041; H01L 2933/005; H01L 2933/0058; H01L 2933/0066

(57) ABSTRACT

A light-emitting device includes: a light-emitting element having a first surface as a light extraction surface, a second surface on an opposite side of the first surface, and a lateral surface connecting the first surface and the second surface and including an element electrode on the second surface; a substrate including a wiring member electrically connected to the element electrode; a light-transmissive member disposed above the first surface of the light-emitting element and allowing light from the light-emitting element to pass through; an inorganic member including a plurality of voids and disposed, on the substrate, on a lateral surface or lateral to the light-emitting element and on a lateral surface of the light-transmissive member; and a light-reflective member in contact with at least part of the inorganic member. A portion of the light-reflective member is impregnated in at least a portion of the plurality of voids.

### CROSS-REFERENCE TO RELATED APPLICATIONS

The present application is a continuation application of PCT Application No. PCT/JP2023/019402, filed May 24, 2023, which claims priority to JP Application No. 2022-087869, filed May 30, 2022, and JP Application No. 2023-083178, filed May 19, 2023. The contents of these applications are incorporated herein by reference in their entireties.

### BACKGROUND

### 1. Technical Field

The present disclosure relates to a light-emitting device and a method for manufacturing the light-emitting device.

### 2. Description of Related Art

A light-emitting device including a first light-reflective member disposed on a lateral surface of a light-emitting element and a second light-reflective member disposed on a lateral surface of the first light-reflective member is proposed (see, for example, Japanese Patent Publication No. 2010-192629). This light-emitting device desirably suppresses a decrease in luminous flux.

### SUMMARY

An object of an aspect of the present disclosure is to provide a light-emitting device that can suppress a decrease in luminous flux and a method for manufacturing the light-emitting device.

Alight-emitting device according to the present disclosure includes: a light-emitting element having a first surface as a light extraction surface, a second surface on an opposite side of the first surface, and a lateral surface connecting the first surface and the second surface and including an element electrode on the second surface; a substrate including a wiring member electrically connecting to the element electrode; a light-transmissive member disposed above the first surface of the light-emitting element and allowing light from the light-emitting element to pass through; an inorganic member disposed, on the substrate, on a lateral surface or lateral to the light-emitting element and on a lateral surface of the light-transmissive member; and a light-reflective member in contact with at least part of the inorganic member. The inorganic member may include a plurality of voids, such as fine holes, and a portion of the light-reflective member is disposed in at least a portion of the plurality of voids of the inorganic member.

A light-emitting device according to the present disclosure includes: a light-emitting element having a first surface as a light extraction surface, a second surface on an opposite side of the first surface, and a lateral surface connecting the first surface and the second surface and including an element electrode on the second surface; a substrate including a wiring member electrically connecting to the element electrode; a light-transmissive member disposed above the first surface of the light-emitting element and allowing light from the light-emitting element to pass through; an inorganic member disposed, on the substrate, on a lateral surface or lateral to the light-emitting element and on a lateral surface of the light-transmissive member; and a light-reflective member in contact with at least part of the inorganic member. The inorganic member includes a plurality of voids, and a portion of the light-reflective member is impregnated in at least a portion of the plurality of voids of the inorganic member.

A method for manufacturing a light-emitting device according to the present disclosure includes: preparing a light-emitting element having a first surface as a light extraction surface, a second surface on an opposite side of the first surface, and a lateral surface connecting the first surface and the second surface and including an element electrode on the second surface and a substrate including a wiring member and preparing a wiring substrate in which the element electrode is electrically joined to the wiring member of the substrate; disposing a light-transmissive member on the first surface of the light-emitting element; disposing an inorganic member on a lateral surface or lateral to the light-emitting element and on a lateral surface of the light-transmissive member; and disposing a light-reflective member on an outer edge of the inorganic member. In the step of disposing an inorganic member, the inorganic member is formed with a plurality of voids, and in the step of disposing a light-reflective member, a portion of the light-reflective member is impregnated in at least a portion of the plurality of voids of the inorganic member.

An aspect of the present disclosure can provide a light-emitting device that can suppress a decrease in luminous flux and a method for manufacturing the light-emitting device.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1 is a schematic perspective view illustrating an entire light-emitting device according to an embodiment of the present disclosure.

FIG. 2 is a cross-sectional view taken along line II-II in FIG. 1.

FIG. 3 is a schematic cross-sectional view of an enlarged portion taken along line III-III of FIG. 2.

FIG. 4A is an SEM photograph illustrating a cross section of an inorganic member before impregnation.

FIG. 4B is an SEM photograph illustrating a cross section of an inorganic member after impregnation.

FIG. 5 is a flowchart illustrating a method for manufacturing the light-emitting device according to the embodiment.

FIG. 6A is a schematic view illustrating a method for manufacturing the light-emitting device according to the embodiment.

FIG. 6B is a schematic view illustrating a method for manufacturing the light-emitting device according to the embodiment.

FIG. 6C is a schematic view illustrating a method for manufacturing the light-emitting device according to the embodiment.

FIG. 6D is a schematic view illustrating a method for manufacturing the light-emitting device according to the embodiment.

FIG. 6E is a schematic view illustrating a method for manufacturing the light-emitting device according to the embodiment.

FIG. 6F is a schematic view illustrating a method for manufacturing the light-emitting device according to the embodiment.

FIG. 6G is a schematic view illustrating a method for manufacturing the light-emitting device according to the embodiment.

FIG. 7 is a schematic cross-sectional view illustrating an application example of the light-emitting device according to the embodiment.

FIG. 8A is a schematic perspective view illustrating a modified example of the light-emitting device according to the embodiment.

FIG. 8B is a schematic cross-sectional view taken along line VIIIB-VIIIB in FIG. 8A.

### DETAILED DESCRIPTION OF EMBODIMENT

### Description of Embodiments

A light-emitting device and a method for manufacturing the light-emitting device will be described with reference to the drawings. However, embodiments described below exemplify the light-emitting device and the method for manufacturing the light-emitting device that embody the technical ideas of the present disclosure and are not limited to the following. In addition, dimensions, materials, shapes, relative arrangements, or the like of components described in the present disclosure are not intended to limit the scope of the present invention thereto, unless otherwise specified, and are given for illustrative purposes only. Sizes, positional relationships, and the like of members illustrated in the drawings can be exaggerated or simplified for clarity of description.

### First Embodiment

### Light-Emitting Device

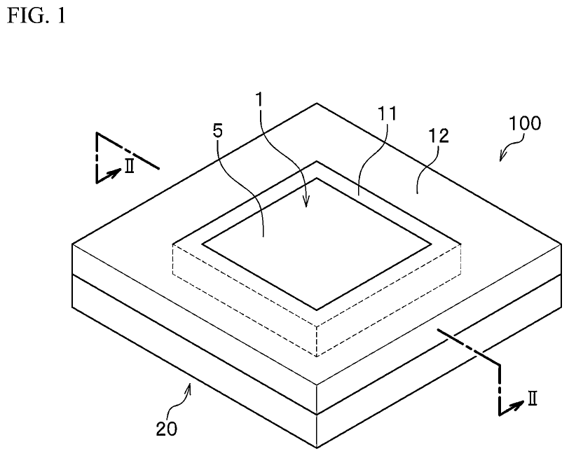

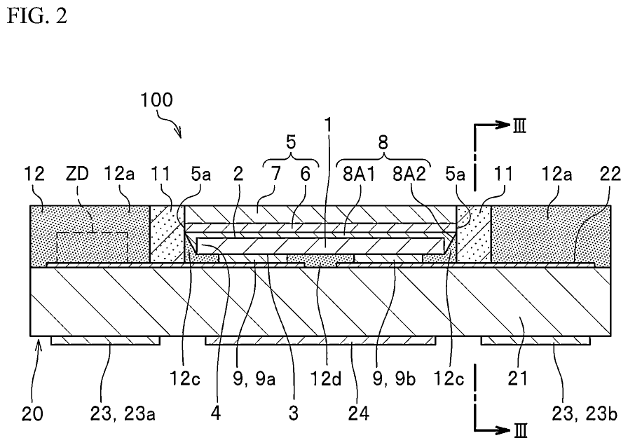

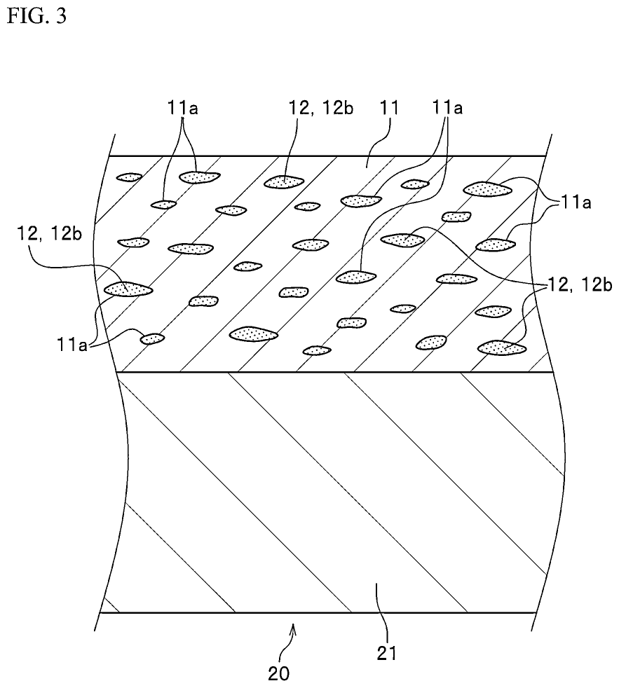

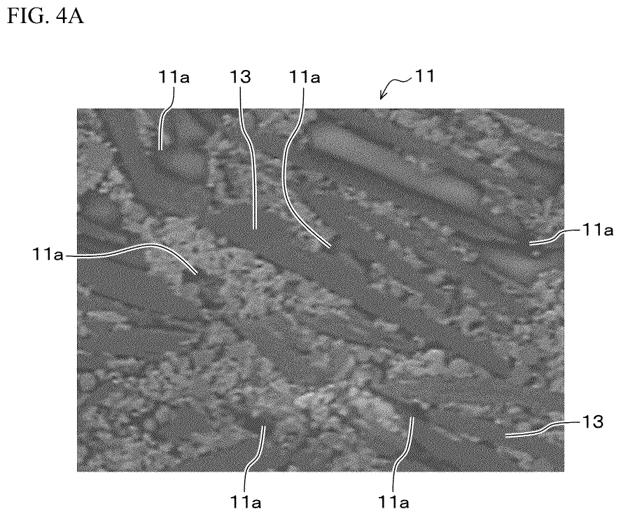

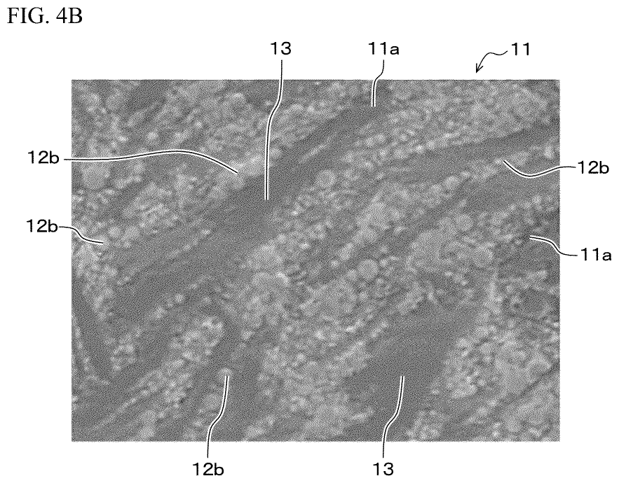

A light-emitting device 100 will be described with reference to FIGS. 1 to 4A and 4B. FIG. 1 is a perspective view schematically illustrating the entire light-emitting device according to a first embodiment. FIG. 2 is a cross-sectional view taken along line II-II in FIG. 1. FIG. 3 is a schematic cross-sectional view of an enlarged portion taken along line III-III of FIG. 2. FIG. 4A is an SEM photograph illustrating a cross section of an inorganic member before impregnation. FIG. 4B is an SEM photograph illustrating a cross section of an inorganic member after impregnation.

As illustrated in FIGS. 1 and 2, the light-emitting device 100 includes: a light-emitting element 1 having a first surface 2 as a light extraction surface, a second surface 3 on an opposite side of the first surface 2, and a lateral surface 4 connecting the first surface 2 and the second surface 3 and including an element electrode 9 on the second surface 3; a substrate 20 including a wiring member 22 electrically connecting to the element electrode 9; a light-transmissive member 5 disposed above the first surface 2 of the light-emitting element 1 and allowing light from the light-emitting element 1 to pass through; an inorganic member 11 disposed, on the substrate 20, on the lateral surface 4 or lateral to the light-emitting element 1 and on a lateral surface 5a of the light-transmissive member 5; and a light-reflective member 12 in contact with at least part of the inorganic member 11. As illustrated in FIG. 3, the inorganic member 11 includes a plurality of voids 11a, and a portion of the light-reflective member 12 is impregnated in at least a portion of the plurality of voids 11a of the inorganic member 11. That is, the inorganic member 11 may include a plurality of fine holes as the plurality of voids 11a, and a portion of the light-reflective member 12 is disposed in at least a portion of the plurality of fine holes of the inorganic member 11. The term “fine hole” as used herein refers to a hole having an opening diameter of about several m.

As an example, the light-emitting device 100 includes an adhesive member 8 disposed between the first surface 2 and the light-transmissive member 5 of the light-emitting element 1. The adhesive member 8 is further disposed as a light-guiding portion 8A2 formed in a fillet shape by a portion of the adhesive member bleeding out onto the lateral surface 4 of the light-emitting element 1, and a third portion 12c serving as a portion of the light-reflective member 12 is disposed in contact with the light-guiding portion 8A2 of the adhesive member 8 disposed on the lateral surface 4 of the light-emitting element 1 and the lateral surface 4 of the light-emitting element 1. A fourth portion 12d serving as a portion of the light-reflective member 12 is disposed in at least a portion between the second surface 3 of the light-emitting element 1 and the upper surface of the substrate 20. Each component of the light-emitting device 100 is described below.

### Light-Emitting Element

The light-emitting element 1 has, for example, a cuboid shape with the first surface 2 serving as a light extraction surface, the second surface 3 opposite to the first surface 2 serving as a bottom surface, and the lateral surface 4 serving as a surface connecting the first surface 2 and the second surface 3. The light-emitting element 1 also includes the element electrode 9 provided on the second surface 3. The light-emitting element 1 includes a semiconductor structural body.

The semiconductor structural body includes an n-side semiconductor layer, a p-side semiconductor layer, and an active layer interposed between the n-side semiconductor layer and the p-side semiconductor layer. The active layer may have a single quantum well (SQW) structure, or may have a multi quantum well (MQW) structure including a plurality of well layers. The semiconductor structure includes a plurality of semiconductor layers each made of a nitride semiconductor. The nitride semiconductor includes a semiconductor having all compositions in which in a chemical formula of InₓAl_{y}Ga_{1-x-y}N (0≤x, 0≤y, and x+y≤1), composition ratios x and y are changed within respective ranges. The light emission peak wavelength of the active layer can be selected as appropriate according to the purpose. The active layer can emit, for example, visible light or ultraviolet light.

The semiconductor structural body may include a plurality of light emitting members each including an n-side semiconductor layer, an active layer, and a p-side semiconductor layer. When the semiconductor structure includes the plurality of light-emitting portions, the plurality of light-emitting portions may each include well layers having different light emission peak wavelengths or well layers having the same light emission peak wavelength. The “same peak wavelength of emitted light” includes a case in which there is a variation of not more than 5 nm. The combination of the light emission peak wavelengths of the plurality of light-emitting portions can be selected as appropriate. For example, in a case in which the semiconductor structure includes two light emitting portions, the combinations of light emitted from each of the two light emitting portions include a combination of blue light and blue light, a combination of green light and green light, a combination of red light and red light, a combination of ultraviolet light and ultraviolet light, a combination of blue light and green light, a combination of blue light and red light, or a combination of green light and red light.

For example, when the semiconductor structure includes three light-emitting portions, the combinations of light emitted from each of the light-emitting portions include a combination of blue light, green light, and red light. Each of the light-emitting portions may include one or more well layers having light emission peak wavelengths different from the light emission peak wavelengths of other well layers.

The element electrode 9 of the light-emitting element 1 includes a first element electrode 9a and a second element electrode 9b spaced from each other on the second surface 3. For example, the light-emitting element 1 is configured such that a conductive member is disposed on the element electrode 9 to create a predetermined gap or more between the second surface 3 of the light-emitting element 1 and the connecting substrate 20. The conductive member may be disposed on the element electrode 9 side of the light-emitting element 1 in advance or may be disposed on the wiring member 22 of the substrate 20 in advance.

### Light-Transmissive Member

The light-transmissive member 5 is a member that is disposed to face the first surface 2 of the light-emitting element 1 and transmits the light from the light-emitting element 1 side to the outside of the light-emitting device. The light-transmissive member 5 may include a member that includes a light-transmissive material and converts the wavelength of the light from the light-emitting element 1. For example, the light-transmissive member 5 has the shape of a rectangular plate in a plan view and includes a wavelength conversion layer 6 including a phosphor, and a light-transmissive layer 7 having transmissivity that is joined to the wavelength conversion layer 6. The wavelength conversion layer 6 provided in the light-transmissive member 5 absorbs at least part of light from the light-emitting element 1 and converts the wavelength into a different wavelength. The light-transmissive member 5 is disposed such that the wavelength conversion layer 6 faces the first surface 2 of the light-emitting element 1 through the adhesive member 8 described later. The light-transmissive member 5 has rectangular shape in a plan view and preferably has an area larger than that of the first surface 2 of the light-emitting element 1. In addition, the surface larger than the first surface 2, which is the light extraction surface of the light-emitting element 1 is joined to the first surface 2 of the light-emitting element 1. That is, the lateral surface 5a corresponding to the outer edge of the light-transmissive member 5 is disposed further outward than the outer edge of the light-emitting element 1 in a plan view.

As for the wavelength conversion layer 6, a formed product obtained by mixing and forming a light-transmissive material such as resin, glass, or an inorganic substance as a binder of the phosphor, for example, can be used. As for the binder, an organic resin binder such as epoxy resin, silicone resin, phenolic resin, or polyimide resin, or an inorganic binder such as glass, for example, can be used. An example of a usable material for the phosphor includes an yttrium-aluminum-garnet-based phosphor (YAG-based phosphor) that is a typical phosphor that can emit a white-based mixed color when suitably combined with a blue light-emitting element. In a case of achieving a light-emitting device 100 that can emit white light, the density of the phosphor included in the wavelength conversion layer 6 is adjusted so as to be able to emit white light.

The light-emitting device 100 uses a blue light-emitting element for the light-emitting element 1 and uses, for example, a YAG-based phosphor and a nitride phosphor having a large red color component as the phosphor, thus allowing for emitting white mixed-color light with a relatively low color temperature, such as a light bulb color.

The YAG-based phosphor is a phosphor containing Y and Al and activated with at least one element selected from rare earth metals. The YAG-based phosphor is excited by light emitted from the light-emitting element 1, and emits light. Examples of a usable material for the YAG-based phosphor include (Re₁₋ₓSmₓ)₃(Al_{1-y}Ga_{y})₅O₁₂:Ce (0≤x<1, 0≤y≤1, where Re is at least one element selected from the group consisting of Y, Gd, and La).

The nitride-based phosphor is a phosphor containing: at least one or more rare earth metals selected from the group consisting of Y, La, Ce, Pr, Nd, Sm, Eu, Gd, Tb, Dy, Ho, Er, and Lu; at least one or more group 2 elements selected from the group consisting of Be, Mg, Ca, Sr, Ba, and Zn; at least one or more group 4 elements selected from the group consisting of C, Si, Ge, Sn, Ti, Zr, and Hf; and N. O may be contained in the compositions of this nitride-based phosphor. It is preferable that the nitride-based phosphor contain at least one selected from the group consisting of a first nitride phosphor having a composition expressed as Formula (1A), and a second nitride-based phosphor having a composition expressed as Formula (1).

M¹₂Si₅N₈:Eu (1A)
where M¹ is an alkaline earth metal element including at least one selected from the group consisting of Ca, Sr, and Ba, and

Sr_{q}CaₛAlₜSiᵤNᵥ:Eu (1B)
where q, s, t, u, and v satisfy 0≤q<1, 0<s≤1, q+≤s1, 0.9≤t≤1.1, 0.9≤u≤1.1, and 2.5≤v≤3.5.

In the formulae expressing the composition of the phosphor, the characters preceding the colon (:) represent a mole ratio for elements in one mole of composition of a host crystal and a phosphor, and the characters following the colon (:) represent an activating element.

It is preferable that the phosphor contain at least one selected from the group consisting of a first fluoride phosphor expressed as the following formula (1C), and a second fluoride phosphor having compositions differing from those of the Formula (1C) and expressed as the Formula (1C′).

$${A}_{c} [ {M}_{1 - b}^{2} {{Mn}^{4 +}}_{b} {F}_{d} ] \qquad ( 1 C )$$

where A includes at least one selected from the group consisting of K⁺, Li⁺, Na⁺, Rb⁺, Cs⁺, and NH₄⁺, and among these, K⁺ is preferable. M² includes at least one element selected from the group consisting of group 4 elements and group 14 elements, and among these, Si and Ge are preferable. b satisfies 0<b<0.2, c is an absolute value of electric charge of [M²_{1-b}Mn⁴⁺_{b}F_{d}] ion, and d satisfies 5<d<7).

$${A}_{{c}^{′}}^{′} [ {M}_{1 - {b}^{′}}^{{2}^{′}} {{Mn}^{4 +}}_{{b}^{′}} {F}_{{d}^{′}} ] \qquad ( 1 {C}^{′} )$$

where A′ contains at least one selected from the group consisting of K⁺, Li⁺, Na⁺, Rb⁺, Cs⁺, and NH₄⁺, and among these, K⁺ is preferable. M^{2′} includes at least one element selected from the group consisting of group 4 elements, group 13 elements, and group 14 elements, and among these, Si and Al are preferable. b′ satisfies 0<b′<0.2, c′ is an absolute value of electric charge of [M^{2′}_{1-b′}Mn⁴⁺_{b′}F_{d′}] ion, and d′ satisfies 5<d′<7).

The light-transmissive layer 7 is a plate-like body that transmits the light from the light-emitting element 1 side to the outside of the light-emitting device. This light-transmissive layer 7 has a size equivalent to the wavelength conversion layer 6, and is disposed such that the lower surface thereof is in contact with the upper surface of the wavelength conversion layer 6. Examples of a usable material for the light-transmissive layer 7 include a plate-shape body made of a transmissive material such as glass or resin. In addition, examples of a usable material for the glass include borosilicate glass, or quartz glass. Examples of a usable material for the resin include silicone resin, or epoxy resin. The light-transmissive layer 7 may include a light-diffusion member. When the density of the phosphor of the wavelength conversion layer 6 increases, colors are more likely to be uneven. However, with a light-diffusion member being included in the light-transmissive layer 7, it is possible to suppress the uneven color and the nonuniformity in brightness. Examples of the light-diffusion member include titanium oxide, barium titanate, aluminum oxide, and silicon oxide.

Although the light-transmissive member 5 composed of two layers: the wavelength conversion layer 6 and the light-transmissive layer 7, is exemplified, the light-transmissive member 5 may be composed of a single layer as one layer containing a phosphor or may be composed of two or more single layers stacked. For example, as disclosed in the JP 2018-172628 A, it is possible to use a sintered compact including a YAG-based phosphor as the light-transmissive member 5. The light-diffusion member may be added to the light-transmissive member 5 as needed. Furthermore, the thickness of the light-transmissive member 5 can be set, for example, in a range from 20 μm to 100 μm, preferably in a range from 20 μm to 50 μm taking into account the mechanical strength.

### Adhesive Member

A portion of the adhesive member 8 forms an adhesive layer 8A1 that causes the light-transmissive member 5 and the light-emitting element 1 to adhere to each other, and the other portion of the adhesive member 8 forms the light-guiding portion 8A2 on the lateral surface 4 of the light-emitting element 1. Increasing the size of the light-guiding portion 8A2 causes the outer edge of the light-guiding portion 8A2 to expand outward, thus allowing for reflecting a larger amount of light in a direction toward the light-transmissive member 5. Thus, it is possible to improve an efficiency in extracting light of the light-emitting device 100. For the adhesive member 8 that constitutes the light-guiding portion 8A2, it is preferable to use a light-transmissive material that can effectively guide light exited from the light-emitting element 1 to the light-transmissive member 5 and also can optically couple the light-emitting element 1 and the light-transmissive member 5. Examples of a usable material for the adhesive member 8 include an organic resin such as epoxy resin, silicone resin, phenolic resin, or polyimide resin, and silicone resin is preferable. The thinner the adhesive layer 8A1 disposed between the light-emitting element 1 and the light-transmissive member 5, the more preferable. This improves the heat dissipating property and also leads to a reduction in a loss of light that passes through the adhesive member 8 between the light-emitting element 1 and the light-transmissive member 5. This improves the output of light of the light-emitting device 100. The adhesive member 8 may include the above-described phosphor.

It is preferable to use an inorganic material including a plurality of voids for the adhesive member 8 similarly to the inorganic member described later. When the adhesive member 8 is made of an inorganic material, heat from the light-emitting element 1 is more easily dispersed than when a resin is used. The adhesive member 8 including the plurality of voids causes the light from the light-emitting element 1 to be easily transmitted through the adhesive member 8. Further, the wavelength conversion layer 6 being efficiently irradiated with the light transmitted through the adhesive member 8 allows the luminous flux of the light-emitting device to be further improved.

As an example of the inorganic material, it is preferable that at least one selected from the group consisting of boron nitride, silicon nitride, and aluminum nitride is used as an aggregate, and a mixture containing potassium hydroxide and at least one selected from the group consisting of aluminum oxide, titanium oxide, and silicon oxide is used as a binder, similarly to the inorganic member described later.

### Inorganic Member, Light-Reflective Member

As illustrated in FIG. 1, the inorganic member 11 and the light-reflective member 12 surround the light-emitting element 1. Since the inorganic member 11 is disposed on the peripheral edge of the light-emitting element 1, the thermal conductivity is good via the inorganic member 11, and the heat generated by the light-emitting element 1 is diffused to reduce the light emission temperature. As illustrated in FIG. 2, the inorganic member 11 is disposed on the upper surface of the substrate 20 at the lateral surface 4 or to the side of the light-emitting element 1 and at a lateral surface 5a of the light-transmissive member 5. As illustrated in FIG. 1, the inorganic member 11 is disposed in a rectangular and annular shape around the light-emitting element 1 following the shape of the light-emitting element 1. As illustrated in FIG. 3, the inorganic member 11 internally includes the plurality of voids 11a. The inorganic member 11 can come into contact with the lateral surface of the light-transmissive member 5. Thus, the heat generated at the light-transmissive member 5 can be directly released to the inorganic member 11 side. In particular, when the light-transmissive member 5 includes a phosphor, heat is easily generated during wavelength conversion by the phosphor, and thus the generated heat can be efficiently released to the inorganic member 11.

The inorganic member 11 includes, for example, an aggregate 13 containing an inorganic material, a light-diffusion material, and a binder that bonds together the aggregate 13 and the light-diffusion material. The aggregate 13 containing the inorganic material is, for example, at least one selected from the group consisting of boron nitride, silicon nitride, aluminum nitride, and aluminum oxide. The light-diffusion material is, for example, at least one selected from the group consisting of titanium oxide, zirconium oxide, and silicon oxide. The binder may comprise, for example, potassium hydroxide and at least one selected from the group consisting of aluminum oxide, titanium oxide, and silicon oxide. The potassium hydroxide included in the binder may be a potassium hydroxide aqueous solution, and when the water content included in the aqueous solution evaporates, the voids 11a are formed inside the inorganic member 11.

Since the inorganic member 11 uses a material having a thermal conductivity higher than that of resins, the inorganic member 11 has a good heat dissipation. However, since the small voids 11a are formed inside, light from the light-emitting element 1 may leak out through the voids 11a. Thus, disposing the light-reflective member 12 on the inorganic member 11, impregnating and disposing a second portion 12b, which is at least a portion of the light-reflective member 12, in the voids 11a of the inorganic member 11, and reducing leakage of light cause the luminous flux of the light-emitting device 100 not to be decreased.

The fine holes corresponding to the voids 11a of the inorganic member 11 are continuous from the outer surface to the inside of the inorganic member 11, and a portion of the light-reflective member 12 is disposed from the outer surface of the inorganic member 11 through the fine holes to the inside of the inorganic member 11. A light-scattering material included in the light-reflective member 12 described later is present in the fine holes of the inorganic member 11.

The light-reflective member 12 is disposed on the substrate 20 so as to be in contact with at least part of the inorganic member 11. The light-reflective member 12 is disposed such that the upper surface thereof is flush with the inorganic member 11. The inorganic member 11 and the light-reflective member 12 are disposed so that the upper surfaces thereof are flush with the light-transmissive member 5. As illustrated in FIG. 1, the light-reflective member 12 is in contact with and covers the outer lateral surface of the inorganic member 11 and is disposed on the substrate 20 in a rectangular and annular shape. Furthermore, the light-reflective member 12 is partially disposed on at least part of the inside of the voids 11a of the inorganic member 11, on the lateral surface 4 of the light-emitting element 1 or the lateral surface of the light-guiding portion 8A2, and on at least part of the second surface 3 of the light-emitting element 1.

The light-reflective member 12 is disposed outward of the inorganic member 11 at the time of manufacturing to be described later, and a portion thereof is impregnated into the voids 11a of the inorganic member 11 before being cured, and is also disposed on the lateral surface 4 of the light-emitting element 1, the lateral surface of the light-guiding portion 8A2, and the second surface 3 side of the light-emitting element 1 via the voids 11a. Thus, the light-reflective member 12 includes at least a first portion 12a disposed outward of the inorganic member 11 and the second portion 12b entering into and filling the voids 11a of the inorganic member 11. Furthermore, the light-reflective member 12 may include the third portion 12c disposed on the lateral surface 4 of the light-emitting element 1 or the lateral surface of the light-guiding portion 8A2, and the fourth portion 12d disposed on a portion of the second surface 3 of the light-emitting element 1. With these components, light is easily reflected. Thus, the luminous flux of the light-emitting device 100 can be further improved.

The third portion 12c and the fourth portion 12d of the light-reflective member 12 are disposed on the lateral surface 4 of the light-emitting element 1 or the lateral surface of the light-guiding portion 8A2 and up to a portion of the second surface 3 of the light-emitting element 1 via the voids 11a of the inorganic member 11.

The light-reflective member 12 is impregnated into, at least some of the voids 11a of the inorganic member 11 and filled therein as the second portion 12b and is more preferably disposed on the lateral surface 4 of the light-emitting element 1 or the lateral surface of the light-guiding portion 8A2 as the third portion 12c. Furthermore, the light-reflective member 12 is most preferably disposed as the fourth portion 12d not only on the second portion 12b and the third portion 12c but also on at least part of the second surface 3 of the light-emitting element 1.

The second portion 12b is preferably impregnated into 50% or more of the voids 11a, more preferably 60% or more, still more preferably 70% or more, and most preferably 80% or more.

The third portion 12c is preferably disposed so as to be in contact with the lateral surface of the light-guiding portion 8A2 or so as to be in contact with the lateral surface of the light-guiding portion 8A2 and the lateral surface of the element electrode 9 of the light-emitting element 1. The third portion 12c may be disposed so as to be in contact with the inner peripheral surface of the inorganic member 11 at a position away from the lateral surface 4 of the light-emitting element 1 on the side of the light-emitting element 1 of the inorganic member 11.

The fourth portion 12d may be in contact with the third portion 12c at the peripheral edge of the second surface 3 of the light-emitting element 1, may be disposed between the first element electrode 9a and the second element electrode 9b forming the element electrode 9, or may be entirely disposed around the element electrode 9 of the light-emitting element 1 between the second surface 3 of the light-emitting element 1 and the upper surface of the substrate 20.

The light-reflective member 12 is preferably made of an insulating material, such as a thermosetting resin or a thermoplastic resin. The light-reflective member 12 can be formed, for example, by using resin or hybrid resin containing one or more of silicone resin, modified silicone resin, epoxy resin, modified epoxy resin, acrylic resin, phenolic resin, BT resin, and PPA and a light-scattering material. Among these materials, it is preferable to use a resin containing, as a base polymer, a silicone resin, which exhibits a good heat resistance property and electrically insulating property and has flexibility. Examples of the light-scattering material include titanium oxide, silicon oxide, zirconium oxide, magnesium oxide, calcium carbonate, calcium hydroxide, calcium silicate, zinc oxide, barium titanate, potassium titanate, aluminum oxide, aluminum nitride, nitriding boron, or mullite. Among these materials, titanium oxide is preferable because it is relatively stable with respect to water content or the like and has a relatively high refractive index.

FIG. 4A is an SEM photograph illustrating a state before the inorganic member 11 is impregnated with the light-reflective member 12. FIG. 4B is an SEM photograph illustrating a state in which the voids 11a of the inorganic member 11 are impregnated with the second portion 12b, which is a portion of the light-reflective member 12. As illustrated in FIG. 4A, the voids 11a (fine holes) of the inorganic member 11 are impregnated with the second portion 12b, which is a portion of the light-reflective member 12 as illustrated in FIG. 4B. In FIG. 4A, many black voids 11a are observed around the aggregate 13 containing the inorganic member 11, but in FIG. 4B, one can see that there are many portions in which the second portion 12b of the light-reflective member 12 is impregnated into a portion of the voids 11a of the inorganic member 11 to fill the voids 11a.

As described above, the light-reflective member 12 is disposed outward of the inorganic member 11, is impregnated in the voids 11a of the inorganic member 11, and is further disposed on the second surface 3 and the lateral surface 4 of the light-emitting element 1. Thus, it is possible to suppress leakage of light and to suppress a decrease in the luminous flux of the light-emitting device 100.

When the adhesive member 8 is made of an inorganic material, a portion of the light-reflective member 12 includes a plurality of voids made of the inorganic material as illustrated in FIG. 4A.

### Substrate

The substrate 20 is for supporting members that constitute the light-emitting device 100. As illustrated in FIG. 2, in the substrate 20, the wiring member 22 for electrically connecting with the element electrode 9 of the light-emitting element 1 is disposed on the upper surface of a base material 21. The substrate 20 further includes, on the lower surface of the base material 21, a positive electrode 23a and a negative electrode 23b as an external connection electrode 23 for electrically connecting an external power supply and the light-emitting device 100. Here, the substrate 20 includes a heat dissipating plate 24 between the positive electrode 23a and the negative electrode 23b spaced apart from them. The substrate 20 includes a via wiring member that electrically connect the wiring member 22 and the external connection electrode 23.

As the material of the base material 21 of the substrate 20, an insulating material less likely to cause light from the light-emitting element 1 or outside light to be transmitted is preferably used. Examples of the insulating material include an inorganic material such as aluminum oxide, aluminum nitride, or LTCC and a resin material such as phenolic resin, epoxy resin, polyimide resin, bismaleimide-triazine (BT) resin, or polyphthalamide. A composite material of an insulating material and a metal member can also be used. In a case of using resin as a material of the base material 21 of the substrate 20, an inorganic filler such as glass fiber, silicon oxide, titanium oxide, and aluminum oxide may be mixed with resin as necessary. As a result, the mechanical strength can be improved, the thermal expansion coefficient can be reduced, and the light reflectance can be improved. The thickness of the substrate 20 is not limited to a particular thickness and can be any thickness according to the purpose and use.

### Operation of Light-Emitting Device

When the light-emitting device 100 is driven, an electric current is supplied from an external power source through the external connection electrode 23 to the light-emitting element 1, and the light-emitting element 1 emits light. The wavelength of a portion of the light directed upward from the light-emitting element 1 is converted by the wavelength conversion layer 6 of the light-transmissive member 5. Accordingly, the light from the light-emitting device 100 is emitted to the outside as, for example, white mixed color light. The light emitted from the light-emitting element 1 in the lateral direction is reflected by the light-guiding portion 8A2, the inorganic member 11, or the light-reflective member 12 so as to be directed toward the light extraction surface side. The light-emitting element 1 is likely to be heated when the light irradiation time is long. However, since the inorganic member 11 is disposed on the peripheral edge of the light-emitting element 1, the heat is diffused more than when a resin is used as the material, and thus it is possible to reduce the bias of the heat at the peripheral edge of the light-emitting element 1.

When the adhesive member 8 between the light-transmissive member 5 and the light-emitting element 1 is made of an inorganic material, the diffusion of heat from the light-emitting element 1 can be promoted more than when the adhesive member 8 is made of a resin.

For example, in a light-emitting device in which the inorganic member 11 is not disposed, the maximum temperature of the peripheral edge of a light-emitting element is 162° C., whereas in the light-emitting device according to the embodiment, the maximum temperature can be reduced to 140° C. In the light-emitting device 100, the light-reflective member 12 is provided around the inorganic member 11, and a portion (the second portion 12b) of the light-reflective member 12 is impregnated into and fill the voids 11a of the inorganic member 11, so that the luminous flux is improved by 10%. Also, in a case in which only the inorganic member 11 is disposed as the light-reflective member at the peripheral edge of the light-emitting element, the bias of heat at the peripheral edge of the light-emitting element 1 is reduced, but the luminous flux is reduced by 12% as compared with the light-emitting device in which no inorganic member is disposed. As described above, in the light-emitting device 100, it is confirmed that the heat dissipation is improved and a decrease in the luminous flux is prevented.

### Method for Manufacturing Light-Emitting Device

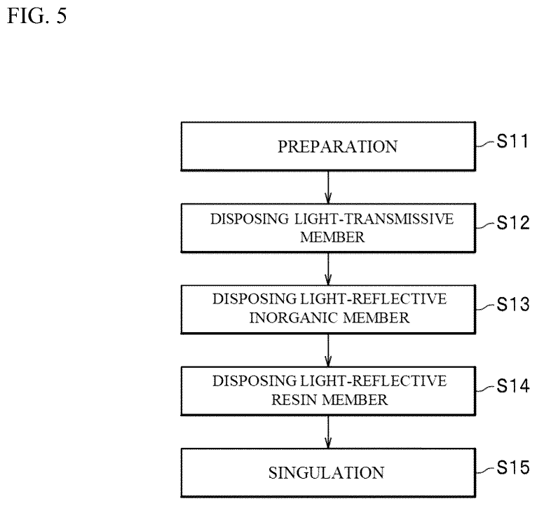

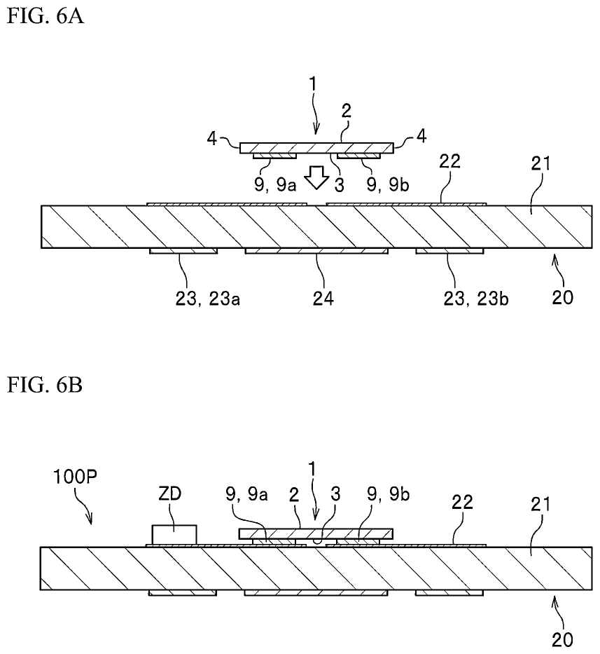

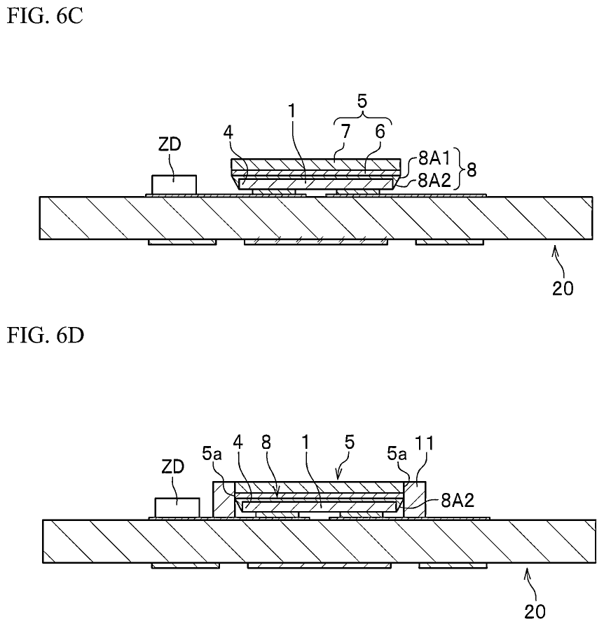

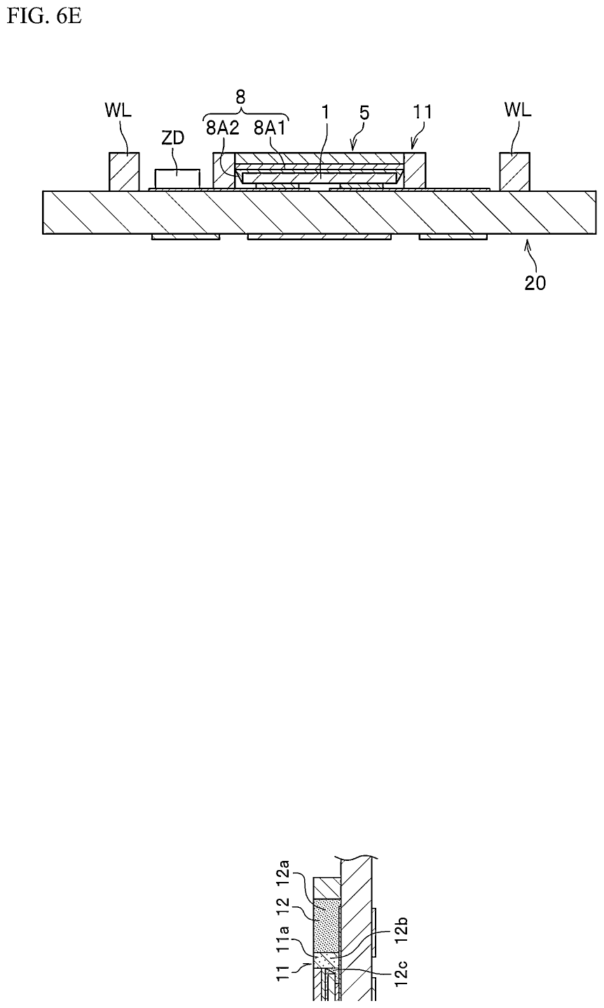

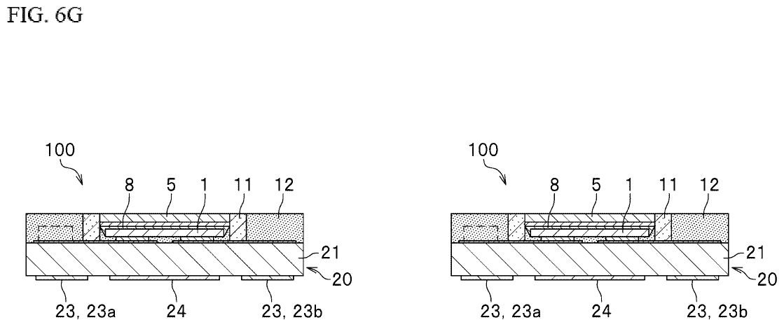

A method for manufacturing a light-emitting device is described below with reference to FIGS. 5 and 6A to 6G. FIG. 5 is a flowchart illustrating a method for manufacturing a light-emitting device. FIGS. 6A to 6G are schematic diagrams each illustrating a method for manufacturing a light-emitting device.

A method for manufacturing the light-emitting device 100 includes step S11 of preparing a light-emitting element having a first surface as a light extraction surface, a second surface on an opposite side of the first surface, and a lateral surface connecting the first surface and the second surface and including an element electrode on the second surface and a substrate including a wiring member and preparing a wiring substrate in which the element electrode is electrically joined to the wiring member of the substrate; step S12 of disposing a light-transmissive member on the first surface of the light-emitting element; step S13 of disposing an inorganic member at the lateral surface or to the side of the light-emitting element and at the lateral surface of the light-transmissive member; and step S14 of disposing a light-reflective member at the outer edge of the inorganic member, wherein in the step S13 of disposing an inorganic member, the inorganic member is formed with a plurality of voids, and in the step S14 of disposing a light-reflective member, at least a portion of the plurality of voids of the inorganic member is impregnated with a portion of the light-reflective member. In the example described herein, after the step S14 of disposing a light-reflective member, a singulation step S15 of singulation for each light-emitting device is performed.

### Step of Preparation

The step S11 of preparation includes preparing the light-emitting element 1 having the first surface 2 serving as a light extraction surface, the second surface 3 on an opposite side of the first surface 2, and the lateral surface 4 connecting the first surface 2 and the second surface 3 and including the element electrode 9 on the second surface 3 and the substrate 20 including the wiring member 22 and preparing a wiring substrate 100 in which the element electrode 9 of the light-emitting element 1 is electrically joined to the substrate 20. In the step S11 of preparation, a conductive member may be used to connect the element electrode 9 of the light-emitting element 1 to the wiring member 22. When a conductive member is used, the conductive member is disposed at a height in the range of 20 m to 110 μm by plating or screen printing, for example. The light-emitting element 1 used here includes the element electrode 9 provided on the second surface 3 and has a rectangular shape in a plan view. The substrate 20 including the via wiring member in a thickness direction, the wiring member 22 connected to the light-emitting element 1 on the upper surface, and the external connection electrode 23 and the heat dissipating plate 24 on the lower surface is prepared. In addition, the conductive member disposed on the element electrode 9 of the light-emitting element 1 is connected to the wiring member 22 of the substrate 20 through an electrically conductive adhesive member to prepare the wiring substrate 100P. The wiring substrate 100P includes a region in which a plurality of the light-emitting elements 1 are connected and the light-emitting devices 100 can be singulated into a plurality of pieces. In the wiring substrate 100P, the light-emitting elements 1 are arranged in the row and column directions at predetermined intervals. In the step S11 of preparation, a semiconductor device such as a Zener diode (ZD) is disposed on the wiring member 22 of the substrate 20.

### Step of Disposing Light-Transmissive Member

The step S12 of disposing a light-transmissive member includes as a step of disposing the light-transmissive member 5 on the first surface 2 of the light-emitting element 1. In this step S12, the adhesive member 8 is disposed on the first surface 2 serving as a light extraction surface of the light-emitting element 1, and the light-transmissive member 5 is disposed using the adhesive member 8. Here, an appropriate amount of the adhesive member 8 is dropped by a supplying device including a nozzle onto the first surface 2 of the light-emitting element 1 of the wiring substrate 100P. To supply the adhesive member 8, the nozzle of the supplying device moves in the row and column directions to drop the adhesive member 8 onto the first surface 2 of the light-emitting element 1. Alternatively, the wiring substrate 100P placed on the placing table is moved by a movement mechanism on the placing table side, and the adhesive member 8 is dropped onto the first surface 2 of each of the plurality of light-emitting elements 1 arranged in the row and column directions. The viscosity of and the amount of drop of the adhesive member 8 to be dropped is set in advance. As an example, the dropping amount of the adhesive member 8 is such an amount that the adhesive member 8 does not leak and drop onto the substrate 20. This is achieved by supplying the adhesive member 8 so that the cross-sectional shape of the light-guiding portion 8A2 has a uniform size at the four sides and four corners of the light-emitting element 1. In this step S12, in order to facilitate the light-guiding portion 8A2 at the corner portion of the light-emitting element 1 being equivalent to the lateral surface 4 of the light-emitting element 1 when viewed in cross section, it is preferable that the adhesive member 8 that has been dropped onto the first surface of the light-emitting element 1 be disposed along the diagonal line of the light-emitting element 1. In other words, a portion of the adhesive member 8 of a suitable amount is preferably dropped at positions close to the four corner portions of the light-emitting element 1 to dispose the adhesive member 8.

In the step S12 of disposing a light-transmissive member, it is preferable to use the light-transmissive member 5 in a state in which the light-transmissive layer 7 and the wavelength conversion layer 6 are joined to each other in advance. Applying a wavelength conversion member including a phosphor to a sheet-shaped light-transmissive member through a printing method forms the light-transmissive layer 7 and the wavelength conversion layer 6, and singulation makes the light-transmissive member 5 a size to be disposed on the first surface 2 of the light-emitting element 1. Although an example of using the light-transmissive member 5 including the wavelength conversion layer 6 is described, the light-transmissive member 5 including only the light-transmissive layer 7 may be used. In this step S12, the light-transmissive member 5 is picked up and disposed one by one above the first surface 2 of the light-emitting element 1 while being pressed with a predetermined pressure. The light-transmissive member 5 is disposed via this step S12, and thus an adhesive layer 8A1 is formed between the lower surface of the light-transmissive member 5 and the first surface 2 of the light-emitting element 1 by the adhesive member 8. Also, the light-guiding portion 8A2 is formed by the adhesive member 8 connecting to the peripheral edge of the lower surface of the light-transmissive member 5 and the lateral surface 4 of the light-emitting element 1.

The adhesive member 8 used in this step S12 may use an inorganic material including a plurality of voids. When the adhesive member 8 is an inorganic material, the plurality of voids are formed by heating the adhesive member 8. For example, the water content in an aqueous solution of potassium hydroxide as a binder used in the inorganic material is evaporated to form a plurality of voids in the inorganic material.

### Step of Disposing Inorganic Member

The step S13 of disposing an inorganic member includes disposing the inorganic member 11 on the lateral surface 4 or to the side of the light-emitting element 1 and the lateral surface 5a of the light-transmissive member 5. In this step S13, the inorganic member 11 is formed around the light-emitting element 1 so as to include the plurality of voids 11a. For example, since the inorganic member 11 includes, for example, the aggregate 13 containing an inorganic material, a light-diffusion material, and a binder that bonds together the aggregate 13 and the light-diffusion material, the inorganic member 11 includes the plurality of voids 11a. In this step S13, after the inorganic member 11 is disposed on the substrate 20 and around the light-emitting elements 1 via a dispenser, the inorganic member 11 is heated and cured. The inorganic member 11 includes the aggregate 13 containing an inorganic material, the light-diffusion material, and the binder, and is placed in contact with the lateral surface 5a of the light-transmissive member 5 of the light-emitting element 1 and heated to form the plurality of voids 11a.

The plurality of voids 11a are formed by evaporation of the solvent or aqueous solution contained in the binder. For example, the plurality of voids 11a are formed by evaporation of the water content in an aqueous solution of potassium hydroxide, but the present disclosure is not limited to using an aqueous solution of potassium hydroxide. The shape of the inorganic member 11 can be achieved by adjusting the shape through a guide or adjusting the viscosity of the member. The dispenser used in this step S13 is preferably moved in the vertical direction, the horizontal direction, or the like relative to the substrate 20 above the fixed substrate 20, for example.

### Step of Disposing Light-Reflective Member

The step S14 of disposing a light-reflective member includes a step of disposing the light-reflective member 12 on the outer edge of the inorganic member 11. In step S14, at least a portion of the plurality of voids 11a of the inorganic member 11 is impregnated with a portion (second portion 12b) of the light-reflective member 12. In this step S14, a portion (third portion 12c) of the light-reflective member is disposed inside the voids 11a of the inorganic member 11 and in contact with the light-guiding portion 8A2 of the adhesive member or the lateral surface 4 of the light-emitting element 1.

That is, in the step S12 of disposing a light-transmissive member, the adhesive member 8 may be disposed as the light-guiding portion 8A2 on the lateral surface 4 of the light-emitting elements 1; in the step S13 of disposing an inorganic member, the inorganic member 11 may be disposed in contact with at least a portion of the lateral surface 4 of the light-emitting element 1; and in the step S14 of disposing a light-reflective member, a portion (third portion 12c) of the light-reflective member 12 may be disposed in contact with the light-guiding portion 8A2 serving as the surface of the adhesive member 8 and the lateral surface 4 of the light-emitting element 1.

A portion of the light-reflective member 12 may be further disposed as the fourth portion 12d in at least a portion between the second surface 3 of the light-emitting element 1 and the upper surface of the substrate 20. The light-reflective member 12 is disposed as the first portion 12a in a rectangular and annular shape at the outer edge of the inorganic member 11 with a guide wall WL installed above the substrate 20.

In the light-reflective member 12, before the first portion 12a is cured, the second portion 12b inside the voids 11a of the inorganic member 11 and, via the voids 11a, the third portion 12c and the fourth portion 12d are preferably disposed. Since the light-reflective member 12 before being cured has fluidity, the light-reflective member 12 can be impregnated into the voids 11a of the inorganic member 11 and pass through the inorganic member 11. Thus, the second portion 12b, the third portion 12c, and the fourth portion 12d can be formed by supplying the light-reflective member 12 from a supplying device such as a dispenser and performing impregnating via the voids 11a of the inorganic member 11. In this step S14, the light-reflective member 12 is supplied so as to be flush with the upper surface of the inorganic member 11. In this step S14, the light-reflective member 12 is cured by heating the light-reflective member 12 at a predetermined temperature.

After the step S14 of disposing a light-reflective member ends, a singulation step is performed, each light-emitting device 100 is cut out for each light-emitting device 100 to manufacture the individual light-emitting device 100. When singulation is performed, it is preferable to perform singulation by cutting only the light-reflective member 12 without cutting the inorganic member 11. This can obtain a desired cross section.

In this method for manufacturing the light-emitting device 100, the guide wall WL is disposed when the light-reflective member 12 is supplied, but the light-reflective member 12 may be supplied without providing the guide wall WL. In the step S12 of disposing a the light-transmissive member, the adhesive member 8 may be disposed as the light-guiding portion 8A2 on the lateral surface 4 of the light-emitting elements 1; and in the step S13 of disposing an inorganic member, the inorganic member 11 may be disposed on at least a portion of the lateral surface 4 of the light-emitting element 1 and a portion (third portion 12c) of the light-reflective member 12 may be disposed in contact with the light-guiding portion 8A2 serving as the surface of the adhesive member 8. The adhesive member 8 may be made of an inorganic material including a plurality of voids. Disposing the third portion 12c and the fourth portion 12d of the light-reflective member 12 can further suppress a decrease in the luminous flux and improve the adhesion with the light-emitting element 1.

When the inorganic member 11 is disposed, the inorganic member 11 may be disposed in a state of being in contact with the lateral surface 5a of the light-transmissive member 5 and in a state of not being in contact with the lateral surface 4 of the light-emitting element 1 or the light-guiding portion 8A2 with space on the side of the light-emitting element 1.

When the element electrode 9 of the light-emitting element 1 and the wiring member 22 of the substrate 20 are joined to each other and disposed via a conductive member, the conductive member may be disposed on the element electrode 9 of the light-emitting element 1 or on the wiring member 22 of the substrate 20 in advance. Furthermore, the element electrode 9 of the light-emitting element 1 may be directly joined to the wiring member 22 of the substrate 20 without the conductive member being provided.

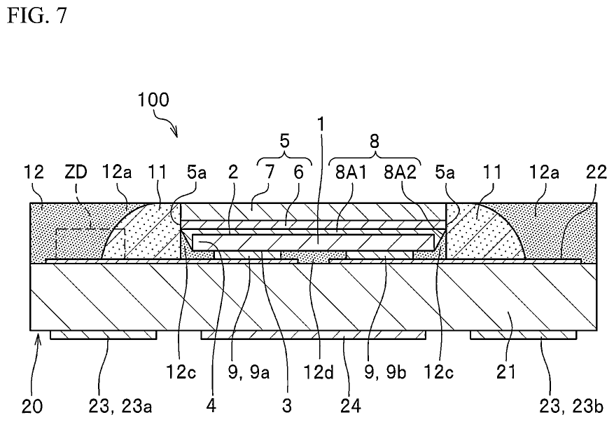

Although the drawings illustrate the inorganic member 11 having a rectangular cross-sectional shape and disposed in a rectangular and annular shape around the light-emitting element 1, as illustrated in FIG. 7, the inorganic member 11 may include a curved surface at an interface with the light-reflective member 12 on an outer edge side, and the curved surface may be curved protruding toward the outer edge side. Even the inorganic member 11 having a curved surface on the outer edge side is desirably formed so as to be flush with the light-reflective member 12 on the upper surface. Since of the inorganic member 11 having a curved surface on the outer edge side has more increased contact area with the light-reflective member 12 than one having a rectangular cross section, a sufficient amount is highly likely to be impregnated from the light-reflective member 12, reducing leakage of light. This can further suppress a reduction of the luminous flux of the light-emitting device 100.

The outer edge side of the inorganic member 11 can be formed into a curved surface by adjusting the viscosity of the inorganic member 11 and adjusting the position of a nozzle for supplying the inorganic member 11. Installing a guide allows the outer edge side of the inorganic member 11 to have a curved surface. Making the light-reflective member 12 flush with the upper surface of the inorganic member 11 is possible by moving a nozzle for supplying the light-reflective member 12 from the outer side to the inorganic member 11 side and dropping the light-reflective member 12 on a portion of the upper surface of the inorganic member 11. Furthermore, grinding the upper surface of only the light-reflective member 12 or the upper surfaces of the light-reflective member 12 and the inorganic member 11 if necessary may cause the light-reflective member 12 to be flush with the upper surface of the inorganic member 11.

In the light-emitting device 100 having the above-described configuration, a portion (fourth portion 12d) of the light-reflective member 12 may be disposed in at least a portion between the second surface 3 of the light-emitting element 1 and the upper surface of the substrate 20. In the case in which the fourth portion 12d serving as a portion of the light-reflective member 12 is disposed between the second surface 3 of the light-emitting element 1 and the upper surface of the substrate 20, the third portion 12c may not be provided leaving a space. That is, the light-reflective member 12 may be in a state in which the first portion 12a, the second portion 12b, and the fourth portion 12d are disposed. In a case of disposing the fourth portion 12d without disposing the third portion 12c, the fourth portion 12d can be achieved by adjusting the supply amount of the light-reflective member 12. Even in such a case, the adhesive member 8 can be made of an inorganic material including a plurality of voids.

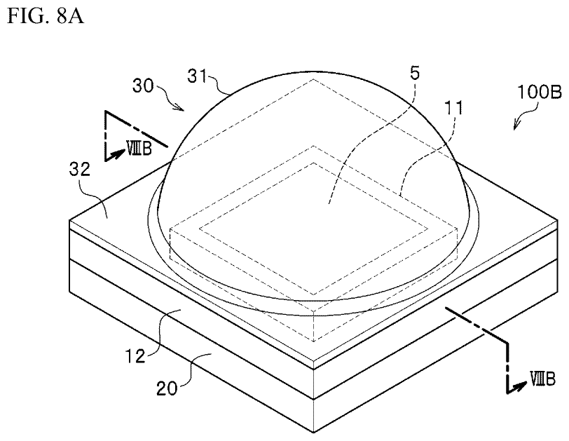

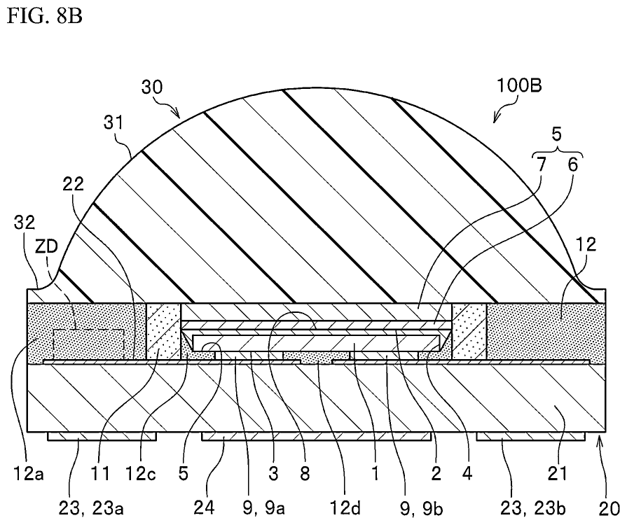

Furthermore, as illustrated in FIGS. 8A and 8B, the light-emitting device may be a light-emitting device 100B in which a lens 30 is disposed facing the light-transmissive member 5 serving as a light extraction surface. FIG. 8A is a schematic perspective view illustrating a modified example of the light-emitting device according to the embodiment. FIG. 8B is a schematic cross-sectional view taken along line VIIIB-VIIIB of FIG. 8A. The same reference characters are assigned to those members already described above, and explanations thereof are omitted as appropriate.

The lens 30 is disposed on the upper surface of the light-transmissive member 5, the upper surface of the inorganic member 11, and the upper surface of the light-reflective member 12 via an adhesive. The lens 30 is formed into a plano-convex lens having a hemispherical shape with a curved surface protruding upward. The lens 30 includes a convex lens portion 31 having a hemispherical shape and a flat flange portion 32 connecting to the lower end of the convex lens portion 31. The lens center of this lens 30 is disposed so as to align with the element center of the light-emitting element 1. The flange portion 32 is formed to have a rectangular shape or square shape in a plan view, is formed larger than the convex lens portion 31, and is formed in a size that substantially matches the shape excluding the lens 30 in a plan view. The lens 30 can focus and output the mixed color light from the light-emitting element 1 and the light-transmissive member 5 to the outside of the light-emitting device 100B through the convex lens portion 31.

Examples of the material of the lens 30 include glass and light-transmissive resins exhibiting excellent weather resistance, such as polycarbonate resin, acrylic resin, epoxy resin, urea resin, and silicone resin. The lens 30 is a member having transmissivity, or a transparent body. The lens 30 may contain a filler such as a diffusing member. With the lens 30 containing a filler, it is possible to reduce a change in light distribution. Examples of the filler include barium titanate, titanium oxide, aluminum oxide, and silicon oxide.

The lens 30 may include a coloring agent. For example, the lens 30 including a blue coloring agent can achieve the light-emitting device 100B that emits blue light, the lens 30 including a green coloring agent can achieve the light-emitting device 100B that emits green light, and the lens 30 including a red coloring agent can achieve the light-emitting device 100B that emits red light. Using these light-emitting devices 100B can manufacture a light source device that can display in full color.

As for the coloring agent, copper phthalocyaninato, C.I. pigment green 36, or N,N′-dimethyl-3,4:9,10-perylenebisdicarbimide can be used. As the coloring agent, a coloring agent including either one of a pigment and a dye may be used.

No specific limitation is applied to the pigment. However, an example of the pigment includes a pigment using an inorganic material or organic material. A pigment or a dye that basically does not convert light from the light-emitting element 1 into light having a different wavelength is preferably used. This is because the wavelength conversion substance is not affected.

The lens 30 may include a light stabilizer. Examples of the light stabilizer include a benzotriazole-based, a benzophenone-based, salicylate-based, cyanoacrylate-based, or hindered amine-based light stabilizer.

The light-emitting device 100B including the lens 30 can emit focused light to the outside through the lens 30.

A method for manufacturing the light-emitting device 100B includes a step of disposing a lens after step S14 of disposing a light-reflective member.

The step of disposing a lens includes a step of disposing the lens 30 having a curved surface protruding upward on the upper surface of the light-transmissive member 5. In this step, the lower surface of the flange portion 32 of the lens 30 is adhered to the upper surface of the light-transmissive member 5, the upper surface of the inorganic member 11, and the upper surface of the light-reflective member 12 via an adhesive with transmissivity. After this step ends, step S16 of singulation is performed to cut out each lens 30 to thus manufacture the light-emitting device 100B.

The light-emitting device according to the present disclosure can be used for a various types of illumination fixtures, a backlight light source of a liquid crystal display, an indoor display, various display devices such as an advertisement or a destination information sign, or the like.

1. A light-emitting device, comprising:
a light-emitting element having a first surface as a light extraction surface, a second surface on an opposite side of the first surface, and a lateral surface connecting the first surface and the second surface and comprising an element electrode on the second surface;
a substrate comprising a wiring member electrically connecting to the element electrode;
a light-transmissive member disposed above the first surface of the light-emitting element and allowing light from the light-emitting element to pass through;
an inorganic member disposed, on the substrate, on a lateral surface or lateral to the light-emitting element and on a lateral surface of the light-transmissive member; and
a light-reflective member in contact with at least part of the inorganic member, wherein
the inorganic member comprises a plurality of voids, and
a portion of the light-reflective member is disposed in at least a portion of the plurality of voids of the inorganic member.

2. A light-emitting device, comprising:
a light-emitting element having a first surface as a light extraction surface, a second surface on an opposite side of the first surface, and a lateral surface connecting the first surface and the second surface and comprising an element electrode on the second surface;
a substrate comprising a wiring member electrically connecting to the element electrode;
a light-transmissive member disposed above the first surface of the light-emitting element and allowing light from the light-emitting element to pass through;
an inorganic member disposed, on the substrate, on a lateral surface or lateral to the light-emitting element and on a lateral surface of the light-transmissive member; and
a light-reflective member in contact with at least part of the inorganic member, wherein
the inorganic member includes a plurality of first voids, and
a portion of the light-reflective member is impregnated in at least a portion of the plurality of first voids of the inorganic member.

3. The light-emitting device according to claim 1, comprising
an adhesive member disposed between the first surface of the light-emitting element and the light-transmissive member.

4. The light-emitting device according to claim 3, wherein
the adhesive member is further disposed on the lateral surface of the light-emitting element, and
the light-reflective member is disposed partially in contact with the adhesive member disposed on the lateral surface of the light-emitting element.

5. The light-emitting device according to claim 3, wherein
the adhesive member is further disposed on the lateral surface of the light-emitting element, and
the light-reflective member is disposed partially in contact with the lateral surface of the light-transmissive member.

6. The light-emitting device according to claim 1, wherein a portion of the light-reflective member is disposed in at least a portion between the second surface of the light-emitting element and an upper surface of the substrate.

7. The light-emitting device according to claim 1, wherein the inorganic member comprises a curved surface at an interface with the light-reflective member on an outer edge side, and
the curved surface is curved protruding toward the outer edge side.

8. The light-emitting device according to claim 1, wherein the inorganic member comprises an aggregate containing an inorganic material, a light-diffusion material, and a binder that bonds together the aggregate and the light-diffusion material.

9. The light-emitting device according to claim 8, wherein
the aggregate comprises at least one selected from the group consisting of boron nitride, silicon nitride, aluminum nitride, and aluminum oxide,
the light-diffusion material comprises at least one selected from the group consisting of titanium oxide, zirconium oxide, and silicon oxide, and
the binder comprises potassium hydroxide and at least one selected from the group consisting of aluminum oxide, titanium oxide, and silicon oxide.

10. The light-emitting device according to claim 3, wherein the adhesive member is an inorganic material including a plurality of second voids.

11. The light-emitting device according to claim 9, wherein the inorganic material comprises at least one selected from boron nitride, silicon nitride, and aluminum nitride, and wherein the binder comprises potassium hydroxide and at least one selected from the group consisting of aluminum oxide, titanium oxide, and silicon oxide.

12. A method for manufacturing a light-emitting device, the method comprising:
preparing a light-emitting element having a first surface as a light extraction surface, a second surface on an opposite side of the first surface, and a lateral surface connecting the first surface and the second surface and comprising an element electrode on the second surface and a substrate comprising a wiring member and preparing a wiring substrate in which the element electrode is electrically joined to the wiring member of the substrate;
disposing a light-transmissive member on the first surface of the light-emitting element;
disposing an inorganic member on a lateral surface or lateral to the light-emitting element and on a lateral surface of the light-transmissive member; and
disposing a light-reflective member on an outer edge of the inorganic member, wherein
in the step of disposing the inorganic member, the inorganic member is formed with a plurality of first voids, and
in the step of disposing the light-reflective member, a portion of the light-reflective member is impregnated in at least a portion of the plurality of first voids of the inorganic member.

13. The method for manufacturing a light-emitting device according to claim 12, wherein
in the step of disposing the light-transmissive member, an adhesive member is disposed between the first surface of the light-emitting element and the light-transmissive member.

14. The method for manufacturing a light-emitting device according to claim 13, wherein
in the step of disposing the light-transmissive member, the adhesive member is disposed on the lateral surface of the light-emitting element,
in the step of disposing the inorganic member, the inorganic member is disposed on at least part of the lateral surface of the light-emitting element, and
in the step of disposing the light-reflective member, the light-reflective member is disposed partially in contact with a surface of the adhesive member.

15. The method for manufacturing a light-emitting device according to claim 13, wherein
in the step of disposing the light-transmissive member, the adhesive member is disposed on the lateral surface of the light-emitting element,
in the step of disposing the inorganic member, the inorganic member is disposed on at least part of the lateral surface of the light-emitting element, and
in the step of disposing the light-reflective member, the light-reflective member is disposed partially in contact with a surface of the adhesive member and the lateral surface of the light-emitting element.

16. The method for manufacturing a light-emitting device according to claim 12, wherein
via the step of disposing the light-reflective member, a portion of the light-reflective member is disposed in at least a part between the second surface of the light-emitting element and an upper surface of the substrate.

17. The method for manufacturing a light-emitting device according to claim 12, further comprising heating and curing the inorganic member i after the inorganic member is disposed on the substrate and around the light-emitting element.

18. The method for manufacturing a light-emitting device according to claim 12,
wherein in the step of disposing the inorganic member, the inorganic member comprises a curved surface at an interface with the light-reflective member on an outer edge side,
the curved surface is curved protruding toward the outer edge side, and
in the step of disposing the light-reflective member, the light-reflective member is disposed flush with the inorganic member.

19. The method for manufacturing a light-emitting device according to claim 13, wherein in the step of disposing the light-transmissive member, the adhesive member is an inorganic material including a plurality of second voids.

20. The light-emitting device according to claim 1, wherein the plurality of voids comprise a plurality of fine holes.

21. The light-emitting device according to claim 2, wherein the plurality of first voids comprise a plurality of fine holes.
